(19) United States
(12) Patent Application Publication
(10) Pub. No.: US 2014/0210483 A1
(43) Pub. Date: Jul. 31, 2014

(54) PROCESSING DEVICE FOR BATTERY PACK AND PROCESSING METHOD THEREFOR

(71) Applicant: Masatoshi UCHIDA, Toyota-shi (JP)

(72) Inventor: Masatoshi UCHIDA, Toyota-shi (JP)

(73) Assignee: TOYOTA JIDOSHA KABUSHIKI KAISHA, Toyota-shi (JP)

(21) Appl. No.: 14/162,236

(22) Filed: Jan. 23, 2014

(30) Foreign Application Priority Data
Jan. 25, 2013 (JP) 2013-012482

(51) Int. Cl. G01R 31/36

(52) U.S. Cl. CPC G01R 31/362
USPC 324/434

(57) ABSTRACT

A processing device for a battery pack including a plurality of batteries has a voltage detection section configured to detect the voltage of each of the batteries, a first processing section configured to perform first processing for discharging the battery pack, and a second processing section configured to perform second processing for individually charging the batteries. The second processing section is configured to suppress a voltage drop by performing the second processing on the battery of which the voltage value has been reduced to a first predetermined value during the discharging in the first processing.

### INCORPORATION BY REFERENCE

The disclosure of Japanese Patent Application No. 2013-012482 filed on Jan. 25, 2013 including the specification, drawings and abstract is incorporated herein by reference in its entirety.

### BACKGROUND OF THE INVENTION

1. Field of the Invention

The invention relates to a processing device for a battery pack, and particularly relates to a technology for reducing variations in the voltages of individual batteries included in a battery pack.

2. Description of Related Art

As a diagnosis method for diagnosing capacity degradation of a battery pack, for example, there is a conventional method in which the voltage of each battery is changed from a diagnosis start voltage to a diagnosis end voltage by discharging the battery, a current value during the discharging is accumulated, and the degradation state of the battery pack is determined based on the accumulated current amount.

Japanese Patent Application Publication No. 2011-064571 (JP 2011-064571 A) discloses the following remaining life diagnosis method. The use condition and life records (charging characteristics of a life battery, and the like) of the life battery are associated with each other and are stored in a database as life information.

When the remaining life of a target battery to be diagnosed is determined, a life charging voltage variation ΔVmcli is acquired from a corresponding area corresponding to the use condition of the target battery to be diagnosed in the database. In addition, a diagnosis charging voltage variation ΔVmccu when the target battery to be diagnosed is charged by a charging sequence is acquired. A remaining life distance Rd and a remaining life time Rt of the target battery to be diagnosed are calculated from the relationship between the acquired diagnosis charging voltage variation ΔVmccu and life charging voltage variation ΔVmcli.

When the capacity degradation diagnosis described above is performed, it is necessary to reduce variations in the voltages of the individual batteries included in the battery pack. That is, by setting the voltages of the individual batteries to the diagnosis start voltage, it is possible to improve diagnosis accuracy. On the other hand, the use of a vehicle by a user is limited during the capacity degradation diagnosis, and hence it is necessary to set the voltages of the batteries to the diagnosis start voltage early and execute diagnosis processing.

### SUMMARY OF THE INVENTION

The invention establishes a state where the capacity degradation can be diagnosed in a short time period while securing the diagnosis accuracy of the capacity degradation of the battery pack.

A first aspect of the invention relates to a processing device for a battery pack including a plurality of batteries. The processing device has a voltage detection section configured to detect a voltage of each of the batteries, a first processing section configured to perform first processing for discharging the battery pack; and a second processing section that performs second processing for individually charging the batteries. The second processing section is configured to suppress a voltage drop by performing the second processing on the battery of which a voltage value has been reduced to a first predetermined value during the discharging in the first processing.

A second aspect of the invention relates to a processing device for a battery pack including a plurality of batteries. The processing device has a voltage detection section configured to detect a voltage of each of the batteries, a third processing section configured to perform third processing for charging the battery pack, and a fourth processing section configured to perform fourth processing for individually discharging the batteries. The fourth processing section is configured to suppress a voltage rise by performing the fourth processing on the battery of which a voltage value has been increased to a third predetermined value during the charging by the third processing.

A third aspect of the invention relates to a processing method for a battery pack including a plurality of batteries. The processing method includes executing charge processing for charging each of the batteries of which a voltage value has been reduced to a first predetermined value while executing discharge processing for discharging the battery pack to thereby suppress a voltage drop.

A fourth aspect of the invention relates to a processing method for a battery pack including a plurality of batteries. The processing method includes executing discharge processing for discharging each of the batteries of which a voltage value has been increased to a third predetermined value while executing charge processing for charging the battery pack to thereby suppress a voltage rise.

According to the invention, it is possible to establish the state where the capacity degradation can be diagnosed in a short time period while securing the diagnosis accuracy of the capacity degradation of the battery pack.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a block diagram of a battery diagnosis device;

FIG. 2 is a flowchart showing processing executed by the battery diagnosis device; and

FIG. 3 is a flowchart showing processing executed by a battery diagnosis device of a second embodiment.

### DETAILED DESCRIPTION OF EMBODIMENTS

### First Embodiment

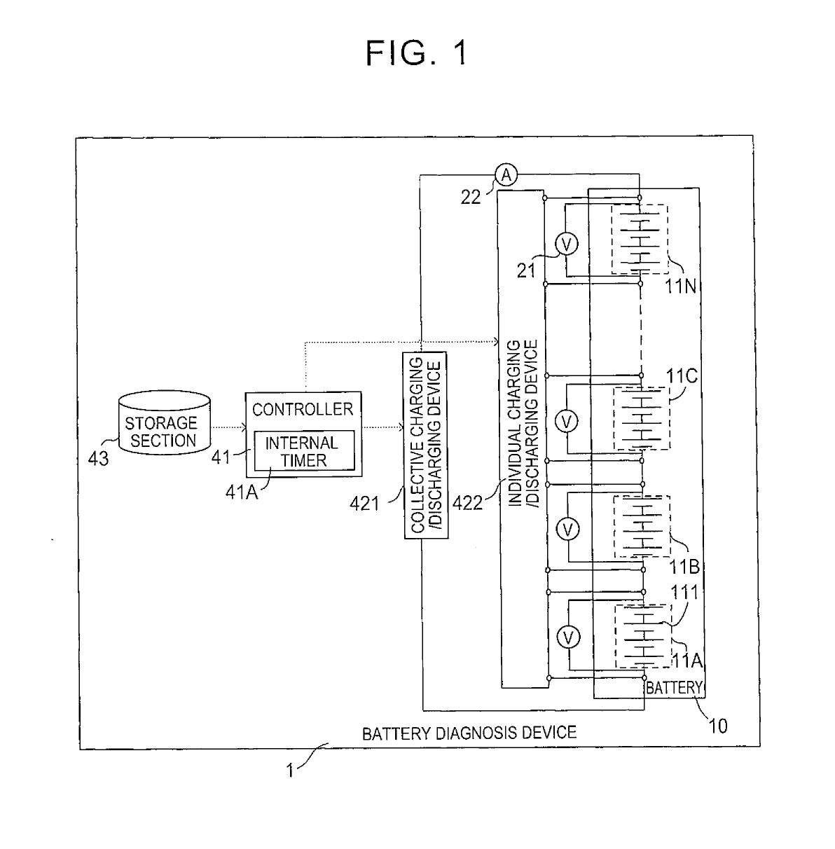

With reference to FIG. 1, a description will be given of a battery diagnosis device (can be regarded as a processing device for a battery pack) as an embodiment of the invention. FIG. 1 is a block diagram of the battery diagnosis device, and arrows in a dotted line indicate the sending direction of a signal or data. A battery diagnosis device 1 is used to perform a degradation diagnosis of a battery 10 (can be regarded as a battery pack) mounted on a vehicle.

The vehicle may be a hybrid vehicle that uses a motor that generates running energy by electric power supplied from the battery 10 and an internal combustion engine as power sources, or an electric vehicle that uses only the motor as the power source. The hybrid vehicle includes what is called a plug-in hybrid vehicle capable of charging the battery 10 using a power supply outside the vehicle. The battery diagnosis device 1 can be provided separately from the vehicle. The battery diagnosis can be performed at, e.g., a dealer or the like.

The battery diagnosis device 1 includes the battery 10, voltage sensors 21, a current sensor 22, a storage section 43, a controller 41, a collective charging/discharging device 421, and an individual charging/discharging device 422.

The battery 10 includes a plurality of battery blocks 11A to 11N. Each of the battery blocks 11A to 11N includes a plurality of cells 111, and the battery blocks 11A to 11N are connected in series. The plurality of the cells 111 are connected in series. The numbers of the cells 111 included in the individual battery blocks 11A to 11N may be the same. The cell 111 may be a secondary battery such as a lithium ion battery or a nickel metal hydride battery, or a capacitor. The cell 111 may also be a single battery cell or a battery module in which a plurality of battery cells are connected. Herein, the battery cell is a minimum element capable of charging and discharging.

The voltage sensor 21 (can be regarded as a voltage detection section) is provided in each of the battery blocks 11A to 11N. The voltage sensor 21 acquires information on the voltage (i.e., block voltage) of each of the battery blocks 11A to 11N, and outputs the acquired information to the controller 41 via a communication path that is not shown. The current sensor 22 acquires a current value outputted by the battery 10, and outputs the acquired current value to the controller 41 via a communication path that is not shown.

The collective charging/discharging device 421 includes a high load and a high-voltage charging section, and the controller 41 performs control that causes the electric power of the battery 10 to be discharged to the high load, and charges the battery 10 by using the high-voltage charging section. Note that the high load and the high-voltage charging section may be independent of each other as separate devices. The individual charging/discharging device 422 includes a low load and a low-voltage charging section, and the controller 41 performs control that causes the electric power of the battery blocks 11A to 11N to be discharged to the low load, and charges the battery blocks 11A to 11N by using the low-voltage charging section. Note that the low load and the low-voltage charging section may be independent of each other as separate devices. In addition, the collective charging/discharging device 421 and the individual charging/discharging device 422 may be configured as one device.

That is, the collective charging/discharging device 421 executes processing for charging and discharging the entire battery 10, while the individual charging/discharging device 422 executes processing for individually charging and discharging the battery blocks 11A to 11N. The high-voltage charging section is capable of charging the battery 10 at a charge rate higher than that of the low-voltage charging section. The discharge rate of the battery 10 is higher in a case where the high load is driven than in a case where the low load is driven. That is, in a case where the high load is operated, energy larger than that in a case where the low load is operated is required, and hence it is necessary to increase the discharge rate of the battery 10.

The controller 41 executes processing for maintaining the block voltage of each of the battery blocks 11A to 11N in the vicinity of a diagnosis start lower limit voltage Vsmin by controlling the collective charging/discharging device 421 and the individual charging/discharging device 422, and the detail thereof will be described in connection with a flowchart later. The controller 41 may be a central processing unit (CPU) or micro processing (MPU), and may include an application specific integrated circuit (ASIC) circuit that executes at least a part of processing performed by the CPU or the like. The number of CPUs may be one or plural. For example, the number of CPUs that control the collective charging/discharging device 421 and the individual charging/discharging device 422 may be one or plural. The controller 41 includes an internal timer 41A. The count result of the internal timer 41 is used when the battery diagnosis is performed. The storage section 43 stores a processing program of processing performed by the controller 41 and various information required when the processing program is executed.

In the embodiment, first processing performed by a first processing section is implemented by cooperation between the collective charging/discharging device 421 and the controller 41. In the embodiment, second processing performed by a second processing section is implemented by cooperation between the individual charging/discharging device 422 and the controller 41. The battery blocks 11A to 11N can be regarded as a plurality of batteries.

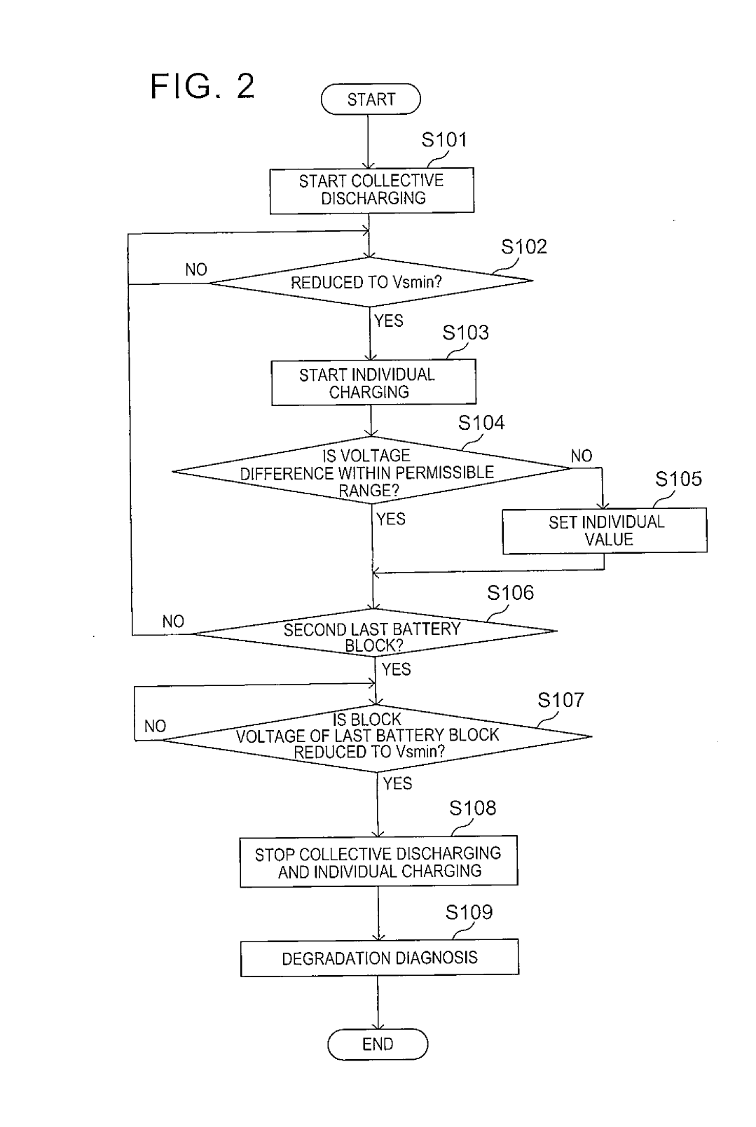

Next, with reference to the flowchart of FIG. 2, a description will be given of a method for maintaining the block voltage of each of the battery blocks 11A to 11N in the vicinity of the diagnosis start lower limit voltage Vsmin. In step S101, the controller 41 reads the discharge rate stored in the storage section 43, and causes the collective charging/discharging device 421 to execute collective discharging of the battery 10 (can be regarded as the first processing). Herein, when the discharge rate stored in the storage section 43 is set to a high value, the speed of the processing is increased and, when the discharge rate is set to a low value, it becomes easy to finely adjust the block voltage of each of the battery blocks 11A to 11N. Consequently, in accordance with the purpose when the battery diagnosis is performed, the discharge rate can be set to an appropriate value. By executing the collective discharging, the block voltage of each of the battery blocks 11A to 11N is constantly reduced.

In step S102, the controller 41 determines which block voltage is reduced to the diagnosis start lower limit voltage Vsmin (can be regarded as a first predetermined value). The diagnosis start lower limit voltage Vsmin is stored in the storage section 43, and can be set to an appropriate value. In the embodiment, as will be described later, an accumulated current amount when the individual battery blocks 11A to 11N are charged is acquired in the degradation diagnosis. Accordingly, the diagnosis start lower limit voltage Vsmin is preferably set to a voltage value exhibited when the state of charge (SOC) of the battery 10 is low such that the accumulated current value is easily acquired.

In a case where any of the block voltages is reduced to the diagnosis start lower limit voltage Vsmin (in the embodiment, the block voltage of the battery block 11A is assumed to be the block voltage that is reduced thereto) (Yes in step S102), the controller 41 executes processing for individually charging the battery block 11A (can be regarded as the second processing) by using the individual charging/discharging device 422 in step S103. The charge rate at the time of the individual charging is stored in the storage section 43. This charge rate is set to a value equal to or lower than the discharge rate of the collective charging/discharging device 421. However, when the charge rate of the individual charging is set to an extremely low value, the voltage drop of the battery block 11A cannot be sufficiently suppressed. Consequently, the charge rate is preferably set to a value close to the discharge rate.

In step S104, the controller 41 determines whether or not the difference between the block voltage of the battery block 11A and the diagnosis start lower limit voltage Vsmin is within a permissible range (can be regarded as a second predetermined value) after the lapse of a predetermined time period. The permissible range can be set to a value appropriate from the viewpoint of securement of the target accuracy of the battery diagnosis. Note that the lapse of the predetermined time period can be determined from the count result of the internal timer 41A. In a case where the difference between the block voltage of the battery block 11A and the diagnosis start lower limit voltage Vsmin is not within the permissible range (No in step S104), the voltage drop of the battery block 11A cannot be sufficiently suppressed with the present charge rate, and hence the controller 41 performs processing for increasing the charge rate in step S105.

With the increase in the charge rate, the effect of suppressing the voltage drop of the battery block 11A is enhanced, and it is possible to prevent the block voltage of the battery block 11A from deviating from the diagnosis start lower limit voltage Vsmin.

In a case where the difference between the block voltage of the battery block 11A and the diagnosis start lower limit voltage Vsmin is within the permissible range (Yes in step S104), the processing proceeds to step S106. In step S106, the controller 41 determines whether or not the battery block 11A is the second last battery block of which the block voltage has been reduced to the diagnosis start lower limit voltage Vsmin. In other words, the controller 41 determines whether or not the number of the battery blocks that are not subjected to the individual charging (see step S103) is one.

In a case where the number of the battery blocks that are not subjected to the individual charging is two or more (No in step S106), the processing returns to step S102. That is, the individual charging for suppressing the voltage drop is sequentially performed on the battery block whose block voltage is reduced to the diagnosis start lower limit voltage Vsmin.

In a case where the number of the battery blocks that are not subjected to the individual charging is one (Yes in step S106), the processing proceeds to step S107. In step S107, the controller 41 determines whether or not the block voltage of the last battery block is reduced to the diagnosis start lower limit voltage Vsmin. In other words, the controller 41 determines whether or not the block voltages of all of the battery blocks reach the diagnosis start lower limit voltage Vsmin. However, it is not necessary for the block voltages of all of the battery blocks to maintain the diagnosis start lower limit voltage Vsmin, and it is appropriate for the block voltages thereof to be maintained in the vicinity of the diagnosis start lower limit voltage Vsmin.

In a case where the block voltage of the last battery block is reduced to the diagnosis start lower limit voltage Vsmin (Yes in step S107), the processing proceeds to step S108. In step S108, the controller 41 prohibits the collective discharging performed by the collective charging/discharging device 421 and the individual charging performed by the individual charging/discharging device 422. With this, it is possible to stop the charging/discharging operations of all of the battery blocks 11A to 11N at the same timing while maintaining the block voltages of all of the battery blocks 11A to 11N in the vicinity of the diagnosis start lower limit voltage Vsmin. In addition, processing for causing the block voltages of the battery blocks 11A to 11N to match the diagnosis start lower limit voltage Vsmin after the end of the collective discharging is obviated, and hence it is possible to establish the state where the battery diagnosis can be performed in a short time period.

In step S109, the controller 41 starts the degradation diagnosis of the battery 10. The degradation diagnosis can be performed by charging the above-described battery 10 having small variations in the block voltage up to a diagnosis end voltage and calculating the accumulated current amount during the charging. The diagnosis end voltage can be set to a value appropriate from the viewpoint of prevention of the degradation of the battery 10 by overcharging. Since the battery diagnosis can be executed in the state where variations in the block voltage are small, it is possible to improve the diagnosis accuracy. Note that the accumulated current amount can be calculated based on the detection result of the current sensor 22.

Herein, as the method for maintaining the block voltages of all of the battery blocks 11A to 11N in the vicinity of the diagnosis start lower limit voltage Vsmin, there can be considered a method in which a first relay is provided in each of the battery blocks 11A to 11N, and a bypass circuit provided with a second relay is mounted on each of the battery blocks 11A to 11N. In this case, while prohibiting the discharging of the battery block by sequentially turning off the first relay and turning on the second relay when the block voltage of the battery block reaches the diagnosis start lower limit voltage Vsmin, it is possible to continue the discharging of the remaining battery blocks by using the bypass circuit.

However, in this method, when the first relay is turned off, a large current is caused to flow and variations in the block voltage are increased. In addition, a long time lag is generated between the battery block of which the discharging is stopped first and the battery block of which the discharging is stopped last, and a polarization state is made significantly different between the battery blocks. That is, when the discharging is stopped, the voltage of the battery block is increased by a voltage corresponding to the polarization. Since the displacement amount of the voltage is influenced by an elapsed time after the stop of the discharging, the long time lag increases a difference in the block voltage. As a result, in a subsequent step, it is necessary to perform capacity matching of the battery blocks 11A to 11N. In addition, when the first and second relays are turned on/off, a large load is applied to each of the relays and an instrument malfunction may be caused.

In contrast to this, in the embodiment, since the charging/discharging operations of all of the battery blocks 11A to 11N are ended at the same timing, it is possible to suppress variations in the polarization state between the battery blocks 11A to 11N. In addition, since it is not necessary to turn on/off the relay, the large current is not caused to flow. Consequently, it is not necessary to perform the capacity matching of the battery blocks 11A to 11N in the subsequent step, and it is possible to establish the state where the battery diagnosis can be performed in a short time period.

In addition, according to the configuration of the embodiment, by setting the discharge rate and the like of the collective charging/discharging device 421 and the individual charging/discharging device 422 to appropriate values, it is possible to smoothly maintain the block voltages of the battery blocks 11A to 11N in the vicinity of the diagnosis start lower limit voltage Vsmin.

### First Modification

In the above flowchart, in the case where the difference between the block voltage and the diagnosis start lower limit voltage Vsmin is not within the permissible range (No in step S104), the voltage drop of the block voltage is suppressed by increasing the charge rate of the individual charging/discharging device 422. However, the invention is not limited thereto, and another method may also be used. Another method mentioned above may be a method that suppresses the voltage drop of the block voltage by reducing the discharge rate of the collective charging/discharging device 421. According to this method, it is possible to further reduce the discharge rate of the collective charging/discharging device 421 as compared with the method of the embodiment described above. With this, it is possible to achieve a reduction in processing time and the suppression of variations in the block voltage in a well-balanced manner. In addition, another method mentioned above may also be a method that concurrently performs processing for increasing the charge rate of the individual charging/discharging device 422 and processing for reducing the discharge rate of the collective charging/discharging device 421. According to this method, it is possible to further reduce the discharge rate of the collective charging/discharging device 421. With this, it is possible to further reduce variations in the block voltage.

### Second Modification

In the above-described embodiment, the processing for suppressing the voltage drop of the block voltage and the battery diagnosis processing are implemented by one battery diagnosis device. However, the invention is not limited thereto. The processing for suppressing the voltage drop thereof and the battery diagnosis processing may be implemented by different devices. In this case, the voltage drop of each block voltage may be suppressed by using a collective discharging device (with no charging function) for collectively discharging the battery 10 and an individual charging device (with no discharging function) for individually charging the battery blocks 11A to 11N. In this case, the collective discharging device can be regarded as the first processing section, and the individual charging device can be regarded as the second processing section.

### Second Embodiment

Although the processing for maintaining the block voltages of the battery blocks 11A to 11N in the vicinity of the diagnosis start lower limit voltage Vsmin is performed in the first embodiment, processing for maintaining the block voltages of the battery blocks 11A to 11N in the vicinity of a diagnosis start upper limit voltage Vsmax (can be regarded as a third predetermined value) is performed in the second embodiment. The hardware configuration of the battery diagnosis device is the same as that of the first embodiment so that the description thereof will not be repeated.

In the second embodiment, third processing performed by a third processing section is implemented by cooperation between the collective charging/discharging device 421 and the controller 41. In the second embodiment, fourth processing performed by a fourth processing section is implemented by cooperation between the individual charging/discharging device 422 and the controller 41.

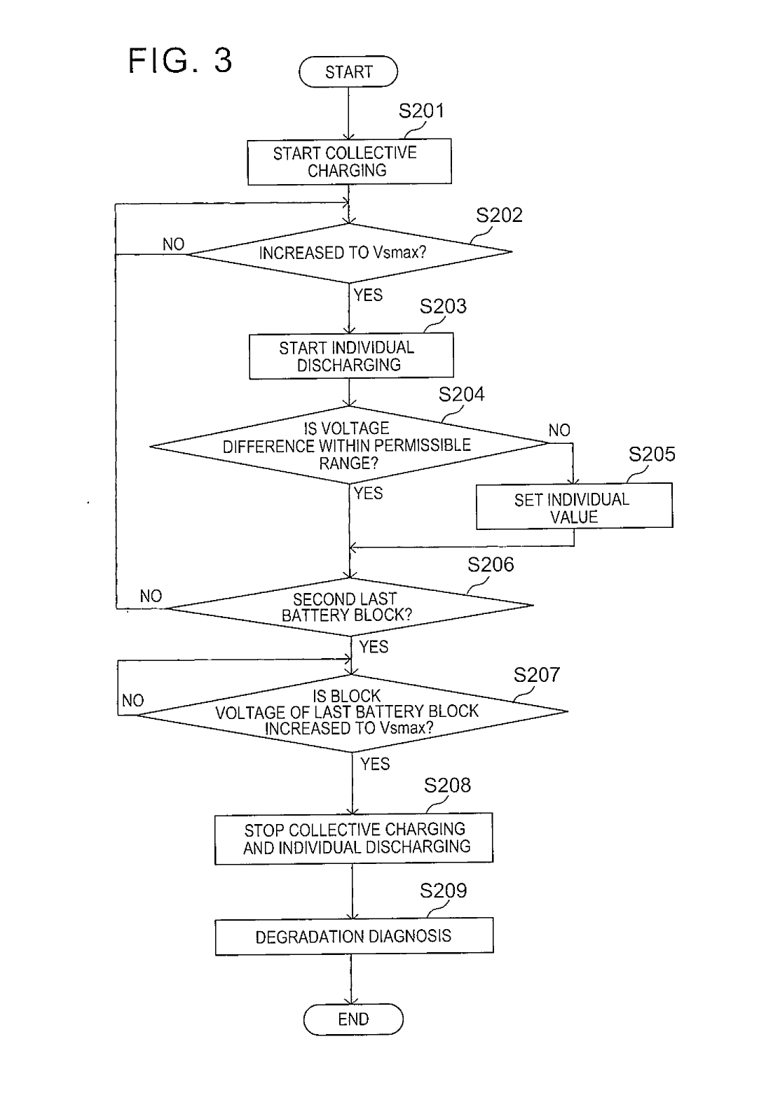

With reference to the flowchart of FIG. 3, a specific description will be given of a method for maintaining the block voltages of the battery blocks 11A to 11N in the vicinity of the diagnosis start upper limit voltage Vsmax. In step S201, the controller 41 reads the charge rate stored in the storage section 43, and performs the collective charging (can be regarded as the third processing) of the battery 10 by using the collective charging/discharging device 421. Herein, when the charge rate stored in the storage section 43 is set to a high value, the speed of the processing is increased and, when the charge rate is set to a low value, it becomes easy to finely adjust the block voltages of the battery blocks 11A to 11N. Consequently, in accordance with the purpose when the battery diagnosis is performed, the charge rate can be set to an appropriate value. By executing the collective charging, the block voltage of each of the battery blocks 11A to 11N is constantly increased.

In step S202, the controller 41 determines which block voltage is increased to the diagnosis start upper limit voltage Vsmax. The diagnosis start upper limit voltage Vsmax is stored in the storage section 43, and can be set to an appropriate value. In the embodiment, as will be described later, the accumulated current amount when the individual battery blocks 11A to 11N are discharged is acquired in the degradation diagnosis. Accordingly, the diagnosis start upper limit voltage Vsmax is preferably set to a voltage value when the SOC of the battery 10 is high such that the accumulated current value is easily acquired.

In a case where any of the block voltages is increased to the diagnosis start upper limit voltage Vsmax (in the embodiment, the block voltage of the battery block 11A is assumed to be the block voltage that is increased thereto) (Yes in step S202), the controller 41 executes processing for individually discharging the battery block 11A (can be regarded as the fourth processing) by using the individual charging/discharging device 422 in step S203. The discharge rate at the time of the individual discharging is stored in the storage section 43. This discharge rate is set to a value equal to or lower than the charge rate of the collective charging/discharging device 421. However, when the discharge rate of the individual discharging is set to an extremely low value, the voltage rise of the battery block 11A cannot be sufficiently suppressed. Consequently, the discharge rate is preferably set to a value close to the charge rate.

In step S204, the controller 41 determines whether or not the difference between the block voltage of the battery block 11A and the diagnosis start upper limit voltage Vsmax is within a permissible range (can be regarded as a fourth predetermined value) after the lapse of a predetermined time period. The permissible range can be set to a value appropriate from the viewpoint of securement of the target accuracy of the battery diagnosis. Note that the lapse of the predetermined time period can be determined from the count result of the internal timer 41A. In a case where the difference between the block voltage of the battery block 11A and the diagnosis start upper limit voltage Vsmax is not within the permissible range (No in step S204), the voltage rise of the battery block 11A cannot be sufficiently suppressed with the present discharge rate, and hence the controller 41 performs processing for increasing the discharge rate in step S205.

With the increase in the discharge rate, the effect of suppressing the voltage rise of the battery block 11A is enhanced, and it is possible to prevent the block voltage of the battery block 11A from deviating from the diagnosis start upper limit voltage Vsmax.

In a case where the difference between the block voltage of the battery block 11A and the diagnosis start upper limit voltage Vsmax is within the permissible range (Yes in step S204), the processing proceeds to step S206. In step S206, the controller 41 determines whether or not the battery block 11A is the second last battery block of which the block voltage has been increased to the diagnosis start upper limit voltage Vsmax. In other words, the controller 41 determines whether or not the number of the battery blocks that are not subjected to the individual discharging (see step S203) is one.

In a case where the number of the battery blocks that are not subjected to the individual discharging is two or more (No in step S206), the processing returns to step S202. That is, the individual discharging for suppressing the voltage rise is sequentially performed on the battery block when the block voltage of the battery block is increased to the diagnosis start upper limit voltage Vsmax.

In a case where the number of the battery blocks that are not subjected to the individual discharging is one (Yes in step S206), the processing proceeds to step S207. In step S207, the controller 41 determines whether or not the block voltage of the last battery block is increased to the diagnosis start upper limit voltage Vsmax. In other words, the controller 41 determines whether or not the block voltages of all of the battery blocks reach the diagnosis start upper limit voltage Vsmax. However, it is not necessary for the block voltages of all of the battery blocks to maintain the diagnosis start upper limit voltage Vsmax, and it is appropriate for the block voltages thereof to be maintained in the vicinity of the diagnosis start upper limit voltage Vsmax.

In a case where the block voltage of the last battery block is increased to the diagnosis start upper limit voltage Vsmax (Yes in step S207), the processing proceeds to step S208. In step S208, the controller 41 prohibits the collective charging by the collective charging/discharging device 421 and the individual discharging by the individual charging/discharging device 422. With this, it is possible to stop the charging/discharging operations of all of the battery blocks 11A to 11N at the same timing while maintaining the block voltages of all of the battery blocks 11A to 11N in the vicinity of the diagnosis start upper limit voltage Vsmax. In addition, processing for causing the block voltages of the battery blocks 11A to 11N to match the diagnosis start upper limit voltage Vsmax after the end of the collective charging is obviated, and hence it is possible to establish the state where the battery diagnosis can be performed in a short time period.

In step S209, the controller 41 starts the degradation diagnosis of the battery 10. The degradation diagnosis can be performed by discharging the above-described battery 10 having small variations in the block voltage up to a diagnosis end voltage and calculating the accumulated current amount during the discharging. The diagnosis end voltage can be set to a value appropriate from the viewpoint of prevention of the degradation of the battery 10 by overdischarging. Since the battery diagnosis can be executed in the state where variations in the block voltage are small, it is possible to improve the diagnosis accuracy. Note that the accumulated current amount can be calculated based on the detection result of the current sensor 22.

Herein, as the method for maintaining the block voltages of all of the battery blocks 11A to 11N in the vicinity of the diagnosis start upper limit voltage Vsmax, there can be considered a method in which a first relay is provided in each of the battery blocks 11A to 11N, and a bypass circuit provided with a second relay is mounted on each of the battery blocks 11A to 11N. In this case, while prohibiting the charging of the battery block by sequentially turning off the first relay and turning on the second relay when the block voltage of the battery block reaches the diagnosis start upper limit voltage Vsmax, it is possible to continue the charging of the remaining battery blocks by using the bypass circuit.

However, in this method, when the first relay is turned off, a large current is caused to flow and variations in the block voltage are increased. In addition, a long time lag is generated between the battery block of which the charging is stopped first and the battery block of which the charging is stopped last, and the polarization state is made significantly different between the battery blocks. That is, when the charging is stopped, the voltage of the battery block is reduced by a voltage corresponding to the polarization. Since the displacement amount of the voltage is influenced by an elapsed time after the stop of the charging, the long time lag increases a difference in the block voltage. As a result, in a subsequent step, it is necessary to perform the capacity matching of the battery blocks 11A to 11N. In addition, when the first and second relays are turned on/off, a large load is applied to each of the relays and the instrument malfunction may be caused.

In contrast to this, in the embodiment, since the charging/discharging operations of all of the battery blocks 11A to 11N are ended at the same timing, it is possible to suppress variations in the polarization state between the battery blocks 11A to 11N. In addition, since it is not necessary to turn on/off the relay, the large current is not caused to flow. Consequently, it is not necessary to perform the capacity matching of the battery blocks 11A to 11N in the subsequent step, and it is possible to establish the state where the battery diagnosis can be performed in a short time period.

In addition, according to the configuration of the embodiment, by setting the discharge rate and the like of the collective charging/discharging device 421 and the individual charging/discharging device 422 to appropriate values, it is possible to smoothly maintain the block voltages of the battery blocks 11A to 11N in the vicinity of the diagnosis start upper limit voltage Vsmax.

### Third Modification

In the above flowchart, in the case where the difference between the block voltage and the diagnosis start upper limit voltage Vsmax is not within the permissible range (No in step S204), the voltage rise of the block voltage is suppressed by increasing the discharge rate of the individual charging/discharging device 422. However, the invention is not limited thereto, and another method may also be used. Another method mentioned above may be a method that suppresses the voltage rise of the block voltage by reducing the charge rate of the collective charging/discharging device 421. According to this method, it is possible to further reduce the charge rate of the collective charging/discharging device 421 as compared with the method of the embodiment described above. With this, it is possible to achieve a reduction in processing time and the suppression of variations in the block voltage in a well-balanced mariner. In addition, another method mentioned above may also be a method that concurrently performs processing for increasing the discharge rate of the individual charging/discharging device 422 and processing for reducing the charge rate of the collective charging/discharging device 421. According to this method, it is possible to further reduce the charge rate of the collective charging/discharging device 421. With this, it is possible to further reduce variations in the block voltage.

### Fourth Modification

In the above-described embodiment, the processing for suppressing the voltage rise of the block voltage and the battery diagnosis processing are implemented by one battery diagnosis device. However, the invention is not limited thereto. The processing for suppressing the voltage rise thereof and the battery diagnosis processing may be implemented by different devices. In this case, the voltage rise of each block voltage may be suppressed by using a collective charging device (with no discharging function) for collectively charging the battery 10 and an individual discharging device (with no charging function) for individually discharging the battery blocks 11A to 11N. In this case, the collective charging device can be regarded as the third processing section, and the individual discharging device can be regarded as the fourth processing section.

### Fifth Modification

In the above-described first and second embodiments, although the method for maintaining the block voltages of the battery blocks 11A to 11N in the vicinity of the diagnosis start upper limit voltage Vsmax and the like is described, the invention is not limited thereto. The invention can also be applied to, e.g., a case where the voltage of each cell 111 is caused to approach the diagnosis start upper limit voltage and the like. In this case, the cells 111 are individually charged/discharged by the individual charging/discharging device 422.

What is claimed is:

1. A processing device for a battery pack including a plurality of batteries, comprising:
a voltage detection section configured to detect a voltage of each of the batteries;
a first processing section configured to perform first processing for discharging the battery pack; and
a second processing section configured to perform second processing for individually charging the batteries, wherein
the second processing section is configured to suppress a voltage drop by performing the second processing on the battery of which a voltage value has been reduced to a first predetermined value during a discharging in the first processing.

2. The processing device for a battery pack according to claim 1, wherein
the second processing section is configured to execute at least one of processing for increasing a charge rate in the second processing and processing for reducing a discharge rate in the first processing in a case where a degree of the voltage drop is larger than a second predetermined value.

3. The processing device for a battery pack according to claim 1, wherein
the second processing section is configured to sequentially perform the second processing on the battery of which the voltage value has been reduced to the first predetermined value, and
the first processing section and the second processing section are configured to stop the first processing and the second processing when the voltage values of all of the batteries have been reduced to the first predetermined value.

4. The processing device for a battery pack according to claim 3, further comprising:
a controller configured to acquire information on a capacity of the battery pack by charging the battery pack by using the first processing section after the first processing and the second processing are stopped, and perform a degradation diagnosis of the battery pack based on the acquired information,
wherein the first processing section is a charging/discharging device that charges and discharges the battery pack.

5. The processing device for the battery pack according to claim 4, wherein
the second processing section is configured to perform the second processing such that the voltage values of the batteries are maintained at the first predetermined value, and
the controller is configured to perform the degradation diagnosis of the battery pack after the second processing.

6. The processing device for a battery pack according to claim 1, wherein
each of the batteries is a battery block including a plurality of cells.

7. A processing device for a battery pack including a plurality of batteries, comprising:
a voltage detection section configured to detect a voltage of each of the batteries;
a third processing section configured to perform third processing for charging the battery pack; and
a fourth processing section configured to perform fourth processing for individually discharging the batteries, wherein
the fourth processing section is configured to suppress a voltage rise by performing the fourth processing on the battery of which a voltage value has been increased to a third predetermined value during a charging by the third processing.

8. The processing device for a battery pack according to claim 7, wherein
the fourth processing section is configured to execute at least one of processing for increasing a discharge rate in the fourth processing and processing for reducing a charge rate in the third processing in a case where a degree of the voltage rise is larger than a fourth predetermined value.

9. The processing device for a battery pack according to claim 7, wherein
the fourth processing section is configured to perform the fourth processing, starting with the battery of which the voltage value has been increased to the third predetermined value, and
the third processing section and the fourth processing section are configured to stop the third processing and the fourth processing when the voltage values of all of the batteries have been increased to the third predetermined value.

10. The processing device for a battery pack according to claim 9, further comprising
a controller configured to acquire information on a capacity of the battery pack by discharging the battery pack by using the third processing section after the third processing and the fourth processing are stopped, and perform a degradation diagnosis of the battery pack based on the acquired information.
wherein the third processing section is a charging/discharging device that charges and discharges the battery pack.

11. The processing device for a battery pack according to claim 10, wherein
the fourth processing section is configured to perform the fourth processing such that the voltage values of the batteries are maintained at the third predetermined value, and
the controller is configured to perform the degradation diagnosis of the battery pack after the fourth processing.

12. The processing device for a battery pack according to claim 7, wherein
each of the batteries is a battery block including a plurality of cells.

13. A processing method for a battery pack including a plurality of batteries, comprising:
executing charge processing for charging each of the batteries of which a voltage value has been reduced to a first predetermined value while executing discharge processing for discharging the battery pack, thereby suppressing a voltage drop.

14. A processing method for a battery pack including a plurality of batteries, comprising:
executing discharge processing for discharging each of the batteries of which a voltage value has been increased to a third predetermined value while executing charge processing for charging the battery pack, thereby suppressing a voltage rise.
